(19) United States
(12) Patent Application Publication
(10) Pub. No.: US 2024/0389303 A1
(43) Pub. Date: Nov. 21, 2024

(54) SEMICONDUCTOR DEVICE HAVING SOURCE/DRAIN REGIONS

(71) Applicant: Samsung Electronics Co., Ltd., Suwon-si (KR)

(72) Inventors: Daeyoung Moon, Suwon-si (KR); Jamin Koo, Suwon-si (KR); Beomseo Kim, Suwon-si (KR)

(21) Appl. No.: 18/663,449

(22) Filed: May 14, 2024

(30) Foreign Application Priority Data
May 15, 2023 (KR) 10-2023-0062324

(51) Int. Cl. H10B 12/00

(52) U.S. Cl. CPC H10B 12/315; H10B 12/482

(57) ABSTRACT

A semiconductor device includes an active region disposed in a substrate, a device isolation layer defining the active region, a gate structure disposed in the substrate and extending in a first horizontal direction to cross the active region, bit line structures crossing the gate structure and extending in a second horizontal direction, intersecting the first horizontal direction, and a contact plug between the bit line structures. The active region includes a first source/drain region, a second source/drain region, and a channel region. The first and second source/drain regions are spaced apart from each other by the gate structure. The first source/drain region includes a first lower region and a first upper region on the first lower region. The first lower region is a first crystal region, and the first upper region is a second crystal region, different from the first crystal region. The contact plug contacts the first upper region.

### CROSS-REFERENCE TO RELATED APPLICATION(S)

This application claims the benefit of priority to Korean Patent Application No. 10-2023-0062324 filed on May 15, 2023 in the Korean Intellectual Property Office, the disclosure of which is incorporated herein by reference in its entirety.

### BACKGROUND

Aspects of the present inventive concept relate to a semiconductor device having source/drain regions.

As demand for high performance, high speed, and/or multifunctionality of semiconductor devices has increased, the degree of integration of semiconductor devices has increased. In manufacturing semiconductor devices with a fine pattern corresponding to the trend for high integration of semiconductor devices, it is necessary to implement patterns having a fine width or a fine separation distance.

### SUMMARY

An aspect of the present inventive concept is to provide a semiconductor device having source/drain regions having a lower region and an upper region.

According to an aspect of the present inventive concept, a semiconductor device may include: an active region disposed in a substrate; a device isolation layer defining the active region; a gate structure disposed in the substrate and extending in a first horizontal direction to cross the active region; bit line structures crossing the gate structure and extending in a second horizontal direction, intersecting the first horizontal direction; and a contact plug disposed between the bit line structures, wherein the active region includes a first source/drain region, a second source/drain region, and a channel region, the first source/drain region and the second source/drain region are spaced apart from each other by the gate structure, the first source/drain region includes a first lower region and a first upper region on the first lower region, the first lower region is a first crystal region, the first upper region is a second crystal region, different from the first crystal region, and the contact plug contacts the first upper region of the first source/drain region.

According to another aspect of the present inventive concept, a semiconductor device may include: an active region disposed in a substrate; a device isolation layer defining the active region; a gate structure disposed in the substrate and extending in a first horizontal direction to cross the active region; bit line structures crossing the gate structure and extending in a second horizontal direction, intersecting the first horizontal direction; and a contact plug disposed between the bit line structures, wherein the active region includes a first source/drain region, a second source/drain region, and a channel region, the first source/drain region and the second source/drain region are spaced apart from each other by the gate structure, the first source/drain region includes a first lower region and a first upper region on the first lower region, the substrate includes a contact hole formed between the bit line structures and exposing the first upper region and the device isolation layer, a portion of the contact plug is disposed in the contact hole and contacts the first upper region, the first lower region has a first etch selectivity with respect to the device isolation layer, and the first upper region has a second etch selectivity higher than the first etch selectivity with respect to the device isolation layer.

According to another aspect of the present inventive concept, a semiconductor device may include: an active region disposed in a substrate; a device isolation layer defining the active region; a gate structure formed in the substrate and disposed in a gate trench extending in a first horizontal direction to cross the active region; bit line structures crossing the gate structure and extending in a second horizontal direction, intersecting the first horizontal direction; a contact plug disposed between the bit line structures; a landing pad on the contact plug; and capacitor structure on the landing pad, wherein the active region includes a first source/drain region, a second source/drain region, and a channel region, the first source/drain region and the second source/drain region are spaced apart from each other by the gate structure, the first source/drain region includes a first lower region and a first upper region on the first lower region, the first lower region is a first crystal region, the first upper region is a second crystal region, different from the first crystal region, and the first upper region of the first source/drain region is in contact with the device isolation layer, the contact plug, and the gate structure.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an embodiment;

FIG. 2A is vertical cross-sectional views of the semiconductor device shown in FIG. 1 taken along lines II-I′ and II-II′;

FIG. 2B is a vertical cross-sectional view of the semiconductor device shown in FIG. 1 taken along line III-III′;

FIG. 3 is an enlarged view of a portion of the semiconductor device shown in FIG. 1;

FIG. 4 is a vertical cross-sectional view of a semiconductor device according to an embodiment; and

FIGS. 5A, 5B, 6A, 6B, 7A, 7B, 8A, 8B, 9A, 9B, 10A, and 10B are vertical cross-sectional views illustrating a sequential process of a method of manufacturing a semiconductor device according to an embodiment.

### DETAILED DESCRIPTION

Hereinafter, embodiments of the present inventive concept will be described with reference to the accompanying drawings.

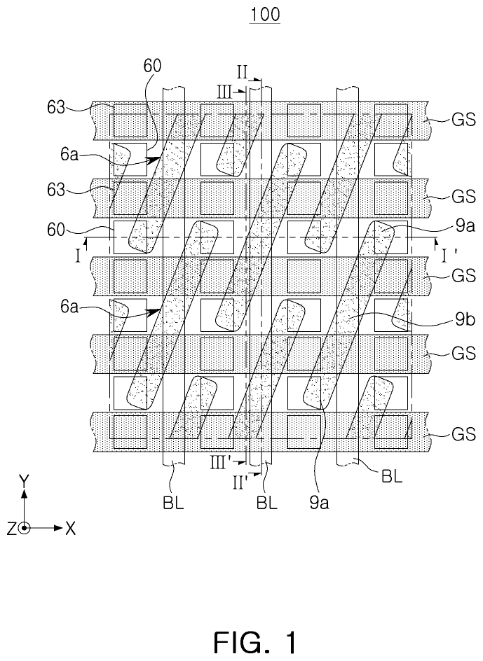

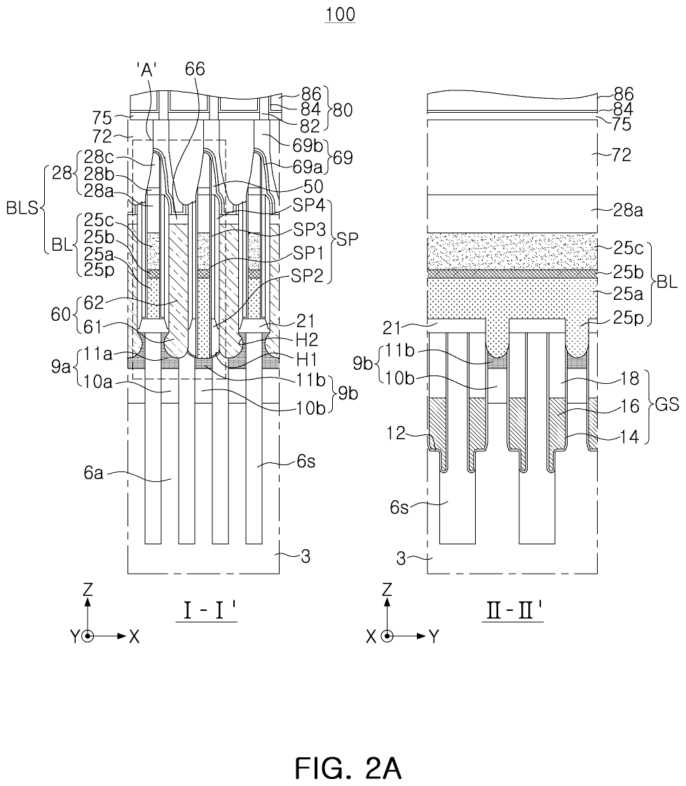

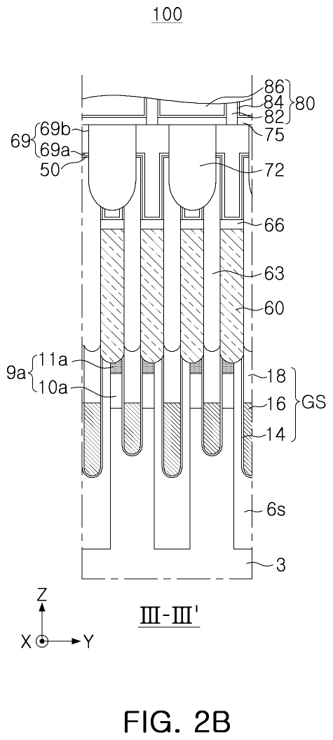

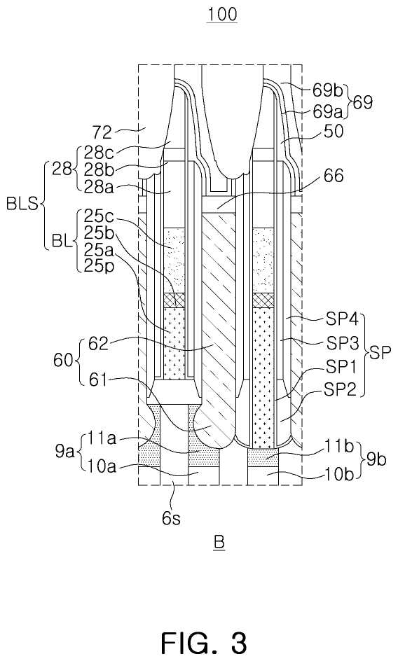

FIG. 1 is a plan view of a semiconductor device according to an embodiment. FIG. 2A is vertical cross-sectional views of the semiconductor device shown in FIG. 1 taken along lines II-I′ and II-II′. FIG. 2B is a vertical cross-sectional view of the semiconductor device shown in FIG. 1 taken along line III-III′. FIG. 3 is an enlarged view of a portion of the semiconductor device shown in FIG. 1.

Referring to FIGS. 1 to 3, a semiconductor device 100 according to an embodiment of the present inventive concept may include a substrate 3, a gate structure GS, a buffer layer 21, a bit line structure BLS, a spacer structure SP, a contact plug 60, a landing pad 69, and a capacitor structure 80. The semiconductor device 100 may be applied to, for example, a cell array of dynamic random access memory (DRAM), but is not limited thereto.

The substrate 3 may include a semiconductor material, such as a group IV semiconductor, a group III-V compound semiconductor, or a group II-VI compound semiconductor. For example, the group IV semiconductor may include silicon, germanium, or silicon-germanium. The substrate 3 may include a silicon substrate, a silicon-on-insulator (SOI) substrate, a germanium substrate, a germanium-on-insulator (GOI) substrate, a silicon-germanium substrate, or an epitaxial layer.

The substrate 3 may include an active region 6a and a device isolation layer 6s. The device isolation layer 6s may be an insulating layer extending downwardly from an upper surface of the substrate 3 and may define the active region 6a. For example, the active region 6a may correspond to a portion of the upper surface of the substrate 3 surrounded by the device isolation layer 6s. In plan view, the active region 6a may have a bar shape having a minor axis and a major axis and may extend in a direction inclined with respect to an X-direction and a Y-direction.

The active region 6a may include first and second source/drain regions 9a and 9b extending to a predetermined depth from the upper surface of the substrate 3 and channel regions. The channel regions may refer to regions disposed below the first and second source/drain regions 9a and 9b. For example, the channel regions may refer to portions of the active region 6a disposed below the first source/drain region 9a and portions of the active region 6a disposed below the second source/drain region 9b. The first and second source/drain regions 9a and 9b may be horizontally spaced apart from each other. The first and second source/drain regions 9a and 9b may be provided as source/drain regions of a transistor. For example, a drain region may be formed between two gate structures GS crossing one active region 6a, and a source region may be formed outside each of the two gate structures GS. For example, the first source/drain region 9a may correspond to the source region, and the second source/drain region 9b may correspond to the drain region. The source region and the drain region may be formed by first and second source/drain regions 9a and 9b by doping or ion implantation of substantially the same impurities, and may be referred to interchangeably according to a circuit configuration of a finally formed transistor. The first and second source/drain regions 9a and 9b may include impurities having a conductivity type opposite to those of the channel regions. For example, the channel regions of the active region 6a may have a P-type conductivity and may have a single crystal structure. The first and second source/drain regions 9a and 9b may have N-type conductivity.

In an embodiment, the first source/drain region 9a may include a first lower region 10a and a first upper region 11a on the first lower region 10a. The second source/drain region 9b may include a second lower region 10b and a second upper region 11b on the second lower region 10b. In an embodiment, the first lower region 10a and the second lower region 10b may be first crystal regions, and the first upper region 11a and the second upper region 11b may be second crystal regions, different from the first crystal regions. For example, the crystal structures of the first upper region 11a and the second upper region 11b may be different from the crystal structures of the first lower region 10a and the second lower region 10b or may not be continuous. In an embodiment, the first crystal region is a single crystal region and may have a single crystal structure having an N-type conductivity. The second crystal region may be a recrystallized region and may have a recrystallized structure having an N-type conductivity. Here, the ‘recrystallized region’ may refer to a region having a structure in which elements are crystallized again by a process, such as annealing, after being amorphized. A content of a first element in the first upper region 11a and the second upper region 11b may be greater than a content of the first element in the first lower region 10a and the second lower region 10b, respectively. For example, the first element may include at least one of carbon (C), silicon (Si), and germanium (Ge). In an embodiment, the first element may further include N-type impurities. In an embodiment, the first element may not be included in the first lower region 10a or the second lower region 10b. The first lower region 10a and the second lower region 10b may include N-type impurities. In an embodiment, a vertical thickness (e.g., in the Z-direction) of the first upper region 11a and the second upper region 11b may be about 20 nm to about 30 nm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The device isolation layer 6s may extend downwardly from the upper surface of the substrate 3 and may define the active regions 6a. The device isolation layer 6s may surround the active regions 6a and may separate the active regions 6a from each other. The device isolation layer 6s may include silicon oxide, silicon nitride, silicon oxynitride, or combinations thereof, and may be formed of a single layer or a plurality of layers.

In plan view, the gate structures GS may extend in the X-direction and may be spaced apart from each other in a Y-direction. In addition, the gate structures GS may cross the active region 6a. For example, two gate structures GS may cross one active region 6a. Transistors each including the gate structure GS and the first and second source/drain regions 9a and 9b may constitute a buried channel array transistor (BCAT).

In a cross-sectional view, the gate structures GS may be buried in the substrate 3, and for example, the gate structures GS may be disposed inside the gate trench 12 formed in the substrate 3. The gate structure GS may include a gate dielectric layer 14, a gate electrode 16, and a gate capping layer 18 disposed inside the gate trench 12. The gate dielectric layer 14 may be conformally formed on an inner wall of the gate trench 12. The gate electrode 16 may be disposed at a lower portion of the gate trench 12, and a gate capping layer 18 may be disposed at an upper portion of the gate structure GS and fill the gate trench 12. A portion of an upper surface of the gate capping layer 18 may be coplanar with the upper surface of the device isolation layer 6s, and, although not illustrated, a portion of the upper surface of the gate capping layer 18 may have an upwardly concave curved surface.

The gate dielectric layer 14 may include silicon oxide or a material having a high dielectric constant. In embodiments, the gate dielectric layer 14 may be a layer formed by oxidizing the active region 6a or a layer formed by deposition. The gate electrode 16 may include a conductive material, for example, at least one of polysilicon (Si), titanium (Ti), titanium nitride (TiN), tantalum (Ta), tantalum nitride (TaN), tungsten (W), tungsten nitride (WN), and aluminum (Al). The gate capping layer 18 may include silicon nitride.

The buffer layer 21 may be disposed on the active region 6a, the device isolation layer 6s, and the gate structure GS. The buffer layer 21 may include silicon oxide, silicon nitride, silicon oxynitride, or combinations thereof. The buffer layer 21 may include a single layer or multiple layers.

The bit line structures BLS may extend in the Y-direction and may be spaced apart from each other in the X-direction. The bit line structure BLS may have a bar shape extending in the Y-direction. The bit line structure BLS may include a bit line BL and a bit line capping layer 28 on the bit line BL. The bit line BL may include a first conductive layer 25a, a second conductive layer 25b, and a third conductive layer 25c sequentially stacked on the buffer layer 21. The first conductive layer 25a may include polysilicon. The second conductive layer 25b may include a metal-semiconductor compound. The metal-semiconductor compound may be, for example, a layer obtained by silicidizing a portion of the first conductive layer 25a. For example, the metal-semiconductor compound may include cobalt silicide (CoSi), titanium silicide (TiSi), nickel silicide (NiSi), tungsten silicide (WSi), or other metal silicides, or may include nitrides, such as TiSiN. The third conductive layer 25c may include a metal material, such as titanium (Ti), tantalum (Ta), tungsten (W), or aluminum (Al). The bit line BL may further include a plug portion 25p disposed below the first conductive layer 25a and extending downwardly to contact the second source/drain region 9b. The plug portion 25p may be located in a bit line contact hole H1 formed in the upper surface of the substrate 3. In plan view, the plug portion 25p may contact a central portion of the active region 6a. The plug portion 25p may electrically connect the active region 6a to the bit line structure BLS. The plug portion 25p may include the same material as that of the first conductive layer 25a. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The bit line capping layer 28 may include a first insulating layer 28a, a second insulating layer 28b, and a third insulating layer 28c disposed on the bit line BL. Side surfaces of the first insulating layer 28a may be coplanar with the first conductive layer 25a, the second conductive layer 25b, and the third conductive layer 25c. The first insulating layer 28a, the second insulating layer 28b, and the third insulating layer 28c may include a silicon oxide, a silicon nitride, a silicon oxynitride, or combinations thereof, and may include, for example, a silicon nitride.

The spacer structures SP may be disposed on both side surfaces of the bit line structures BLS, and may extend in the Y-direction along the side surfaces of the bit line structures BLS. The spacer structure SP may include a first spacer SP1, a second spacer SP2, a third spacer SP3, and a fourth spacer SP4 disposed on side surfaces of the bit line structures BLS. The first spacer SP1 may be conformally disposed along side surfaces of the bit line structure BLS and the bit line contact hole H1. The second spacer SP2 may be disposed on the first spacer SP1 and may fill the bit line contact hole H1. The third spacer SP3 may cover the side surface of the first spacer SP1, and the fourth spacer SP4 may cover the side surface of the third spacer SP3. The third spacer SP3 and the fourth spacer SP4 may cover the upper surface of the second spacer SP2. The first spacer SP1, the second spacer SP2, the third spacer SP3, and the fourth spacer SP4 may include silicon oxide, silicon nitride, silicon oxynitride, or combinations thereof. In an embodiment, the first spacer SP1 and the fourth spacer SP4 may include silicon nitride, the second spacer SP2 may include silicon oxide, and the third spacer SP3 may include an air gap. The spacer structure SP is an example, and the material and the number of layers are not limited thereto and may be variously changed according to aspects of the inventive concept.

The contact plug 60 may be disposed between the bit line structures BLS and may contact the spacer structures SP. In plan view, the contact plugs 60 may be disposed between the bit line structures BLS and between the gate structures GS. The contact plug 60 may be electrically connected to the first source/drain region 9a. In an embodiment, contact plug 60 may include a lower portion 61 and an upper portion 62. The lower portion 61 may be disposed inside the contact hole H2 and may contact the first upper region 11a of the first source/drain region 9a. The upper portion 62 may be disposed on the lower portion 61 and may be located on the substrate 3. In an embodiment, the contact plug 60 may contact only the first upper region 11a and may be spaced apart from the first lower region 10a. For example, a vertical thickness of the lower portion 61 of the contact plug 60 may be smaller than a vertical thickness of the first upper region 11a. The lower end of the lower portion 61 may be located on a level higher than that of the lower end of the first upper region 11a.

The contact plug 60 may include a conductive material, for example, polysilicon (Si), titanium (Ti), titanium nitride (TiN), tantalum (Ta), tantalum nitride (TaN), tungsten (W), tungsten nitride (WN), and aluminum (Al). In an embodiment, the contact plug 60 may include doped polysilicon and may include N-type impurities, such as phosphorus (P), arsenic (As), and antimony (Sb).

A fence structure 63 may be disposed between the bit line structures BLS and overlap the gate structure GS in a vertical direction. The fence structures 63 may be alternately disposed with the contact plugs 60 in the Y-direction. The fence structures 63 may spatially separate the contact plugs 60 from each other and electrically insulate them from each other. The fence structure 63 may have a bar or column shape extending in the vertical direction. A lower surface of the fence structure 63 may contact the gate capping layer 18 of the gate structure GS. In an embodiment, the lower surface of the fence structure 63 may have a downwardly convex curved surface toward the gate capping layer 18, and the upper surface of the gate capping layer 18 may have, although not illustrated, an upwardly concave curved surface. The lower surface of the fence structure 63 may be located on a lower level than the upper surface of the substrate 3. The upper surface of the fence structure 63 may be located at a level higher than the upper surface of the contact plug 60, and the lower surface of the fence structure 63 may be located on a level lower than that of the lower surface of the contact plug 60. The fence structure 63 may include an insulating material, for example, a silicon nitride. The contact plug 60 and the fence structure 63 shown in FIG. 1 are schematically illustrated to describe a positional relationship with other components, and a size and shape may vary according to an embodiment.

The semiconductor device 100 may further include a metal-semiconductor compound layer 66 disposed on the upper surface of the contact plug 60. The metal-semiconductor compound layer 66 may contact a side surface of the spacer structure SP and a side surface of the fence structure 63.

The landing pad 69 may be disposed on the metal-semiconductor compound layer 66 and may include a barrier layer 69a covering the bit line structure BLS, the spacer structure SP, and the fence structure 63. The landing pad 69 may also include a metal layer 69b on the barrier layer 69a. The landing pad 69 may be electrically connected to the first source/drain region 9a of the active region 6a through the contact plug 60. The metal-semiconductor compound layer 66 may include cobalt silicide (CoSi), titanium silicide (TiSi), nickel silicide (NiSi), tungsten silicide (WSi), or other metal silicide. The barrier layer 69a may include at least one of a metal nitride, e.g., titanium nitride (TiN), tantalum nitride (TaN), and tungsten nitride (WN). The metal layer 69b may include a conductive material, for example, at least one of titanium (Ti), tantalum (Ta), tungsten (W), and aluminum (Al).

The semiconductor device 100 may further include an upper insulating spacer 50 covering upper portions of the bit line structure BLS, the spacer structure SP, and the fence structure 63. The upper insulating spacer 50 may be disposed between the bit line structure BLS and the barrier layer 69a, between the spacer structure SP and the barrier layer 69a, and between the fence structure 63 and the barrier layer 69a.

The semiconductor device 100 may further include an insulating pattern 72 disposed between the landing pads 69. An upper surface of the insulating pattern 72 may be coplanar with an upper surface of the landing pad 69, and the insulating pattern 72 may extend downwardly to partially contact the bit line structures BLS. The insulating pattern 72 may spatially separate the landing pads 69 from each other and electrically insulate them from each other.

The semiconductor device 100 may further include an etch stop layer 75 covering upper surfaces of the landing pad 69 and the insulating pattern 72. The capacitor structure 80 may be disposed on the landing pad 69 and the insulating pattern 72. The capacitor structure 80 may include a lower electrode 82, a capacitor dielectric layer 84 and an upper electrode 86. The lower electrode 82 may pass through the etch stop layer 75 and contact the upper surface of the landing pad 69. The capacitor dielectric layer 84 may cover the lower electrode 82 and the etch stop layer 75, and the upper electrode 86 may cover the capacitor dielectric layer 84. The capacitor structure 80 may be electrically connected to the landing pad 69 and the contact plug 60. The lower electrode 82 and the upper electrode 86 may include at least one of a doped semiconductor, a metal nitride, a metal, and a metal oxide. The lower electrode 82 and the upper electrode 86 may include, for example, at least one of polycrystalline silicon, titanium nitride (TiN), tungsten (W), titanium (Ti), ruthenium (Ru), and tungsten nitride (WN). The capacitor dielectric layer 84 may include, for example, at least one of high dielectric constant materials, such as zirconium oxide (ZrO₂), aluminum oxide (Al₂O₃), and hafnium oxide (Hf₂O₃).

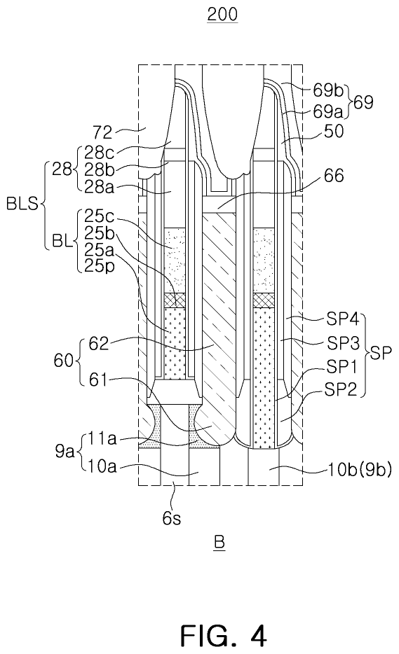

FIG. 4 is a vertical cross-sectional view of a semiconductor device according to an embodiment.

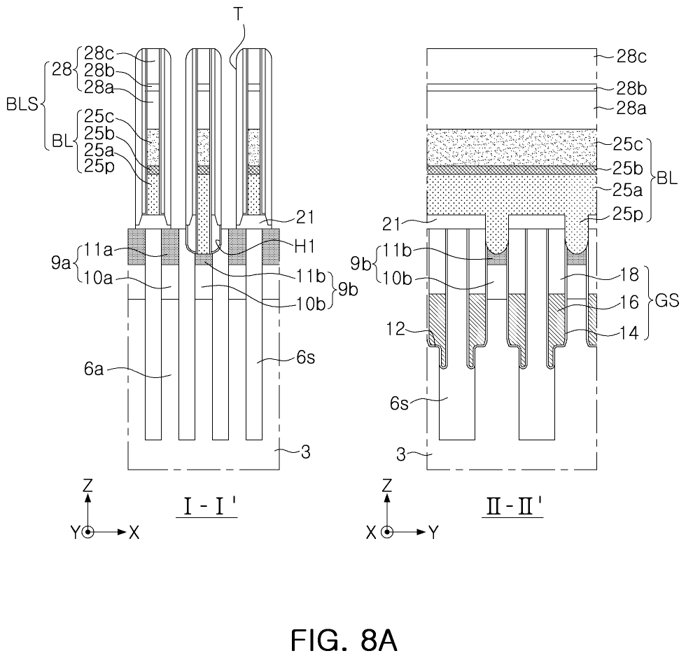

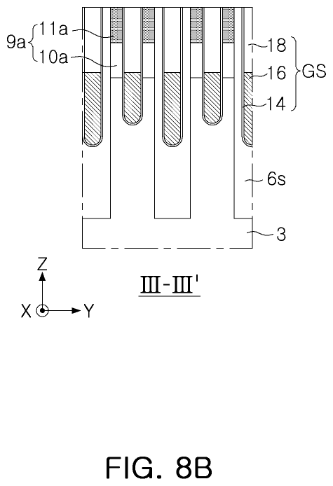

Referring to FIG. 4, the semiconductor device may include the first source/drain region 9a and the second source/drain region 9b disposed in the substrate 3. In an embodiment, the second lower region 10b of the second source/drain region 9b may contact a lower end of the bit line structure BLS. For example, the second lower region 10b may contact the plug portion 25p. When forming the bit line contact hole H1, which will be described below with reference to FIGS. 8A and 8B, the second upper region 11b may be removed, and thus, the second lower region 10b may contact a lower end of the bit line structure BLS.

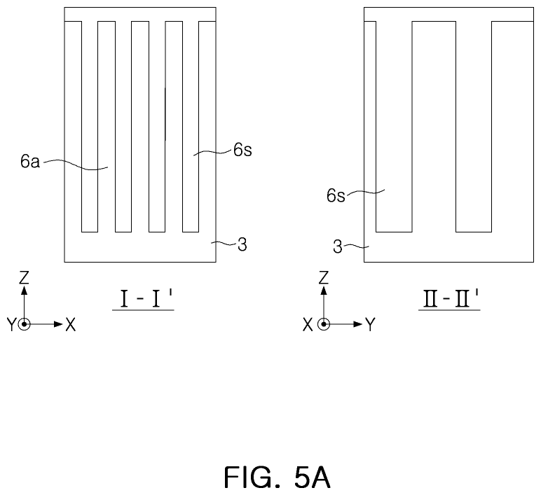

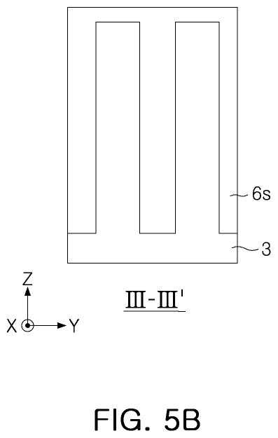

FIGS. 5A to 10B are vertical cross-sectional views illustrating a sequential process of a method of manufacturing a semiconductor device according to an embodiment. Specifically, FIGS. 5A, 6A, 7A, 8A, 9A, and 10A are vertical cross-sectional views taken along lines I-I′ and II-II′ of FIG. 1, and FIGS. 5B, 6B, 7B, 8B, 9B, and 10B are vertical cross-sectional views taken along line III-III′ of FIG. 1.

Referring to FIGS. 5A and 5B, the device isolation layer 6s may be formed in the substrate 3.

The device isolation layer 6s may be formed by forming a trench on the upper surface of the substrate 3 and filling the trench with an insulating material. The device isolation layer 6s may cover the substrate 3. The device isolation layer 6s may define the active regions 6a. For example, the active regions 6a may correspond to a portion of the upper surface of the substrate 3 surrounded by the device isolation layer 6s. In plan view, the active regions 6a may have a bar shape having a minor axis and a major axis, and may be spaced apart from each other. The device isolation layer 6s may include a single layer or a plurality of layers.

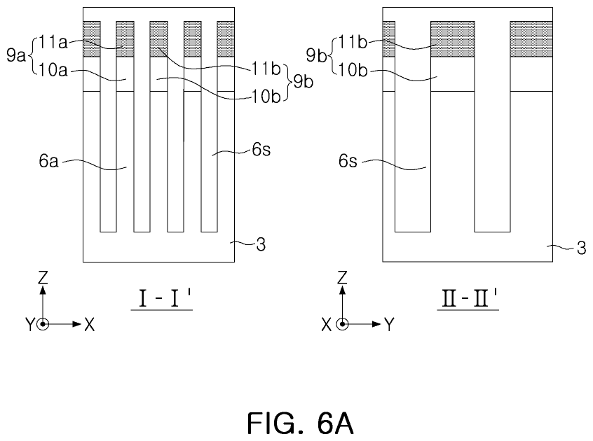

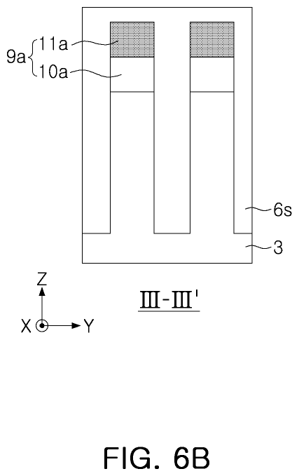

Referring to FIGS. 6A and 6B, a first source/drain region 9a and a second source/drain region 9b may be formed in the active region 6a. For example, the second source/drain region 9b may be formed in the center of the bar-shaped active region 6a, and the first source/drain region 9a may be formed on both sides of the second source/drain region 9b.

In an embodiment, the first source/drain region 9a and the second source/drain region 9b may be formed by doping the active region 6a with impurities through an ion implantation (IIP) process. For example, a first ion implantation process may be performed while the upper surface of the substrate 3 is covered by the device isolation layer 6s. Elements may be implanted into the active region 6a by the first ion implantation process. The elements may be N-type impurities and may include at least one of phosphorus (P), arsenic (As), and antimony (Sb).

After the elements are implanted into the active region 6a, a second ion implantation process may be performed to implant other elements. An ion implantation voltage may be adjusted so that elements implanted in the second ion implantation process may be located on a level higher than that of the elements implanted during the first ion implantation process. In an embodiment, the elements implanted by the second ion implantation process may be implanted at a density of about 1×10¹⁶ atom/cm² to about 1×10¹⁷ atom/cm². In an embodiment, the elements implanted by the second ion implantation process may include at least one of carbon (C), silicon (Si), and germanium (Ge). Upper portions of the first source/drain region 9a and the second source/drain region 9b may be amorphized by the second ion implantation process.

After the first and second ion implantation processes are performed, annealing may be performed. Portions of the first source/drain region 9a and the second source/drain region 9b that are amorphized by the annealing process may be recrystallized. Through the annealing process, the first lower region 10a and the first upper region 11a may be formed in the first source/drain region 9a, and the second lower region 10b and the second upper region 11b may be formed in the second source/drain region 9b. The first lower region 10a and the second lower region 10b may have an N-type conductivity and may include N-type impurities. The first upper region 11a and the second upper region 11b may have N-type conductivity and may include at least one of carbon (C), silicon (Si), and germanium (Ge). In addition, since the first ion implantation process is also performed on the first upper region 11a and the second upper region 11b, the N-type impurities may also be included in the first upper region 11a and the second upper region 11b. A recrystallized structure of the recrystallized first upper region 11a and second upper region 11b may not be continuous with the single crystal structures of the first lower region 10a and the second lower region 10b.

After an annealing process is performed, a portion of the device isolation layer 6s covering the active region 6a may be removed. For example, a chemical mechanical flashing (CMP) process may be performed, and a portion of the device isolation layer 6s may be removed to expose the active region 6a. In some embodiments, an ion implantation process and an annealing process may be performed after the active region 6a is exposed.

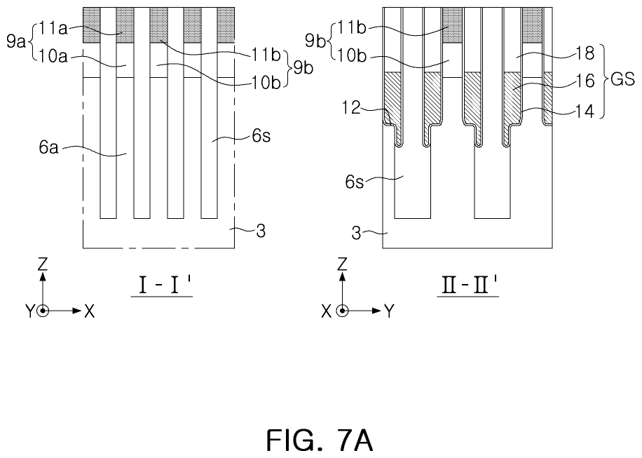

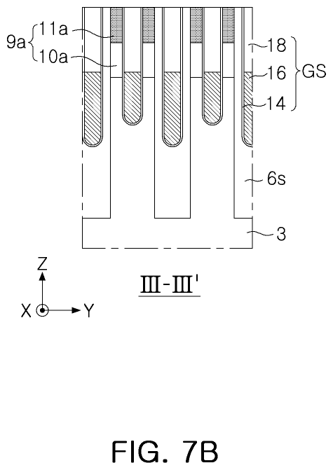

Referring to FIGS. 7A and 7B, gate structures GS may be formed inside the substrate 3. Gate trenches 12 may be formed by anisotropically etching the substrate 3. The gate trenches 12 may extend in the X-direction and may cross the active region 6a and the device isolation layer 6s. The gate structure GS may be formed by forming the gate dielectric layer 14, the gate electrode 16, and the gate capping layer 18 in the gate trench 12. The gate dielectric layer 14 may be conformally formed on the inner wall of the gate trench 12. The gate electrode 16 may be formed by forming a conductive material on the gate dielectric layer 14 and then recessing the conductive material. The gate capping layer 18 may be formed by forming an insulating material on the gate electrode 16 to fill the gate trench 12 and then performing a planarization process. In an embodiment, as shown in FIGS. 7A and 7B, the gate structure GS may be formed deeper in the device isolation layer 6s than in the active region 6a.

Referring to FIGS. 8A and 8B, the buffer layer 21, the bit line structure BLS, and the spacer structure SP may be formed on the substrate 3. The buffer layer 21 may be formed on upper surfaces of the substrate 3, the active region 6a, the device isolation layer 6s, and the gate structure GS. The buffer layer 21 may include a single layer or a plurality of layers.

The bit line structure BLS may be formed on the buffer layer 21. The bit line structure BLS may be formed by forming the bit line contact hole H1 by etching the buffer layer 21 so that the active region 6a is exposed, stacking conductive material layers on the bit line contact hole H1, forming the insulating material layers on the conductive material layers, and patterning the conductive material layers and the insulating material layers. The bit line structures BLS may extend in the Y-direction and may be spaced apart from each other in the X-direction.

The bit line structure BLS may include a bit line BL including a conductive material and a bit line capping layer 28 including an insulating material. The bit line BL may include a first conductive layer 25a, a second conductive layer 25b, and a third conductive layer 25c being sequentially stacked, and the first conductive layer 25a may include a plug portion 25p disposed in the bit line contact hole H1. The bit line capping layer 28 may include a first insulating layer 28a, a second insulating layer 28b, and a third insulating layer 28c being sequentially stacked.

The spacer structure SP may be formed on both side surfaces of the bit line structure BLS. The spacer structure SP may include a first spacer SP1, a second spacer SP2, a third spacer SP3, and a fourth spacer SP4. The first spacer SP1 may be formed by conformally depositing an insulating material along the side surface of the bit line structure BLS and an inner wall of the bit line contact hole H1. The second spacer SP2 may be formed by depositing an insulating material on the first spacer SP1 to fill the bit line contact hole H1. The third spacer SP3 may be formed by depositing an insulating material to cover a side surface of the second spacer SP2 and anisotropically etching the insulating material. The fourth spacer SP4 may be formed to cover a side surface of the third spacer SP3. The spacer structure SP may extend in the Y-direction along the side surface of the bit line structure BLS.

After the spacer structure SP is formed, the buffer layer 21 may be etched by an anisotropic etching process, and a trench T may be formed between the bit line structures BLS. For example, the trench T may be defined by mutually facing side surfaces of adjacent spacer structures SP and may extend in the Y-direction. The trench T may partially expose upper surfaces of the active region 6a and the device isolation layer 6s between the bit line structures BLS.

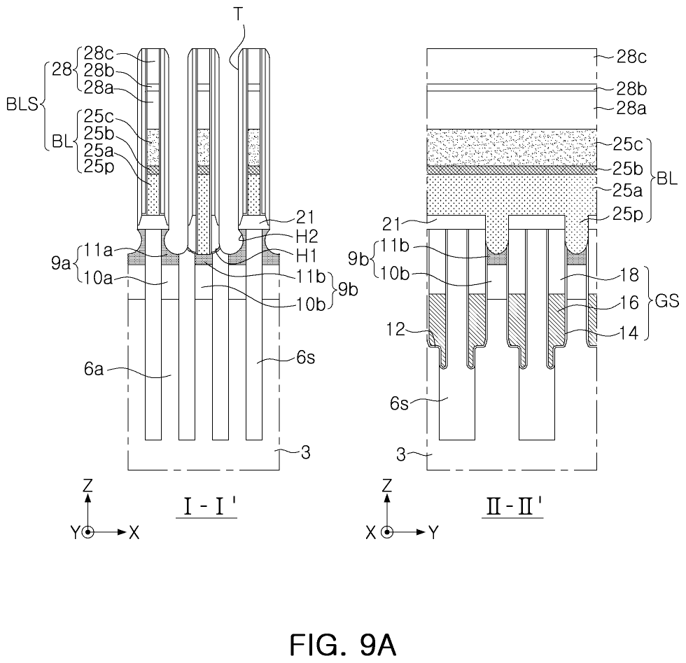

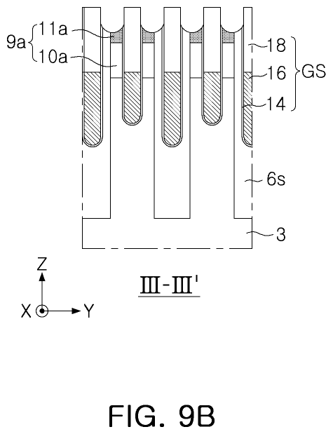

Referring to FIGS. 9A and 9B, a contact hole H2 communicating with the trench T may be formed between the bit line structures BLS. The contact hole H2 may be formed by etching the active region 6a and the device isolation layer 6s. For example, the device isolation layer 6s may be etched by a wet etching process, and the first upper region 11a of the first source/drain region 9a may be etched during the wet etching process. As described above, the first upper region 11a may include at least one of carbon (C), silicon (Si), and germanium (Ge). Accordingly, the first upper region 11a may have etch selectivity with the first lower region 10a. For example, the first upper region 11a may have a higher etch selectivity with respect to the device isolation layer 6s than the first lower region 10a including a first impurity. Specifically, the first lower region 10a may have a first etch selectivity with respect to the device isolation layer 6s, and the first upper region 11a may have a second etch selectivity higher than the first etch selectivity with respect to the device isolation layer 6s. Therefore, during the wet etching process, the first source/drain region 9a may be prevented from being over-etched.

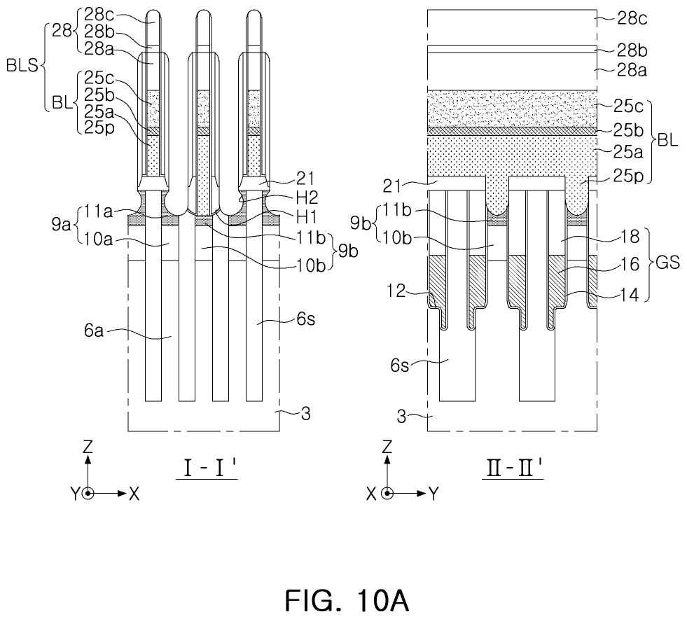

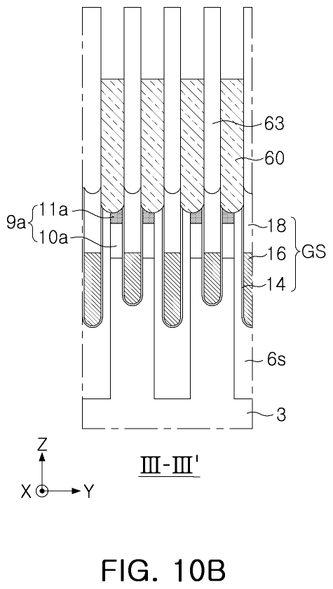

Referring to FIGS. 10A and 10B, the contact plug 60 may be formed in the trench T and the contact hole H2. The contact plug 60 may be formed by filling the trench T with a conductive material. The contact plug 60 may be disposed between the spacer structures SP and may be electrically connected to the first source/drain region 9a. In an embodiment, the contact plug 60 may include doped polysilicon. For example, the contact plug 60 may be deposited and formed with N-type impurities in the trench T. The contact plug 60 may include at least one of phosphorus (P), arsenic (As), and antimony (Sb). After the contact plug 60 is formed, the N-type impurities inside the contact plug 60 may diffuse into the first source/drain region 9a through the first upper region 11a. Accordingly, a doping concentration of the N-type impurities included in the first upper region 11a may be greater than a doping concentration of the N-type impurities included in the first lower region 10a.

The contact plug 60 may include a lower portion 61 and an upper portion 62. The lower portion 61 may be disposed inside the contact hole H2 and may contact the first upper region 11a of the first source/drain region 9a. The upper portion 62 may be disposed on the lower portion 61 and may be located on the substrate 3. In an embodiment, a horizontal width of the lower portion 61 may be greater than a horizontal width of the upper portion 62. For example, the lower portion 61 may protrude in a horizontal direction toward the first source/drain region 9a.

After the contact plug 60 is formed, the fence structure 63 may be formed. The fence structure 63 may be formed by removing portions of the gate structure GS and the contact plug 60 and then filling the removed portions with an insulating material. For example, the fence structures 63 may be formed to overlap the gate structure GS in a vertical direction between the bit line structures BLS. The lower surface of the fence structure 63 may have a downwardly convex curved surface toward the gate structure GS and may contact the upper surface of the gate capping layer 18. The fence structures 63 may be spaced apart from each other in the X- and Y-directions.

After the fence structure 63 is formed, an upper portion of the contact plug 60 may be partially etched. For example, the upper surface of the contact plug 60 may be located on a level lower than that of an upper end of the bit line structure BLS and an upper end of the fence structure 63. The contact plugs 60 may be alternately disposed with the fence structures 63 in the Y-direction between the bit line structures BLS. In some embodiments, the contact plug 60 may be formed after the fence structure 63 is formed first.

During the wet etching process described above with reference to FIGS. 9A and 9B, if the first upper region 11a is not sufficiently etched, a contact area between the first upper region 11a and the contact plug 60 may be reduced, resulting in an increase in contact resistance. If the first upper region 11a is over-etched, a portion of the fence structure 63 may be interposed between the first upper region 11a and the contact plug 60, and the first upper region 11a and the contact plug 60 may not be electrically connected. However, according to the embodiment of the present inventive concept, since the first upper region 11a is formed to have a higher etch selectivity to the device isolation layer 6s than the first lower region 10a, the contact hole H2 may be formed so that the contact area between the first upper region 11a and the contact plugs 60 increases. For example, the first upper region 11a may contact the side surfaces and the lower surface of the lower portion 61 of the contact plug 60. Accordingly, contact resistance between the first source/drain region 9a and the contact plug 60 may be reduced, and electrical characteristics of the semiconductor device may be improved.

Referring back to FIGS. 2A and 2B, the barrier layer 69a and the metal layer 69b may be formed on the bit line structure BLS, the spacer structure SP, and the contact plug 60. The barrier layer 69a and the metal layer 69b may be patterned and filled with an insulating material to form the landing pad 69 and the insulating pattern 72. In an embodiment, the metal-semiconductor compound layer 66 may be formed between the contact plug 60 and the landing pad 69 before the landing pad 69 is formed.

In an embodiment, before the landing pad 69 is formed, the upper insulation spacer 50 covering upper portions of the bit line structure BLS and the spacer structure SP protruding from an upper surface 60_U of the contact plug 60 may be further formed. The barrier layer 69a may conformally cover the upper insulating spacer 50. The upper insulating spacer 50 may also cover an upper portion of the fence structure 63 protruding from the upper surface of the contact plug 60.

The etch stop layer 75 and the capacitor structure 80 may be formed on the landing pad 69 to form the semiconductor device 100. The etch stop layer 75 may be formed to cover upper surfaces of the landing pad 69 and the insulating pattern 72. The capacitor structure 80 may include the lower electrode 82 connected to the landing pad 69 through the etch stop layer 75, the capacitor dielectric layer 84 on the lower electrode 82, and the upper electrode 86 on the capacitor dielectric layer 84.

According to embodiments of the inventive concept, since the upper region of the impurity region has a recrystallized structure, the impurity region may be prevented from being over-etched when a contact hole in which a contact plug is to be disposed is formed. Accordingly, a contact area between the impurity region and the contact plug may increase and contact resistance may decrease.

While embodiments have been shown and described above, it will be apparent to those skilled in the art that modifications and variations could be made without departing from the scope of the present inventive concept as defined by the appended claims.

What is claimed is:

1. A semiconductor device comprising:
an active region disposed in a substrate;
a device isolation layer defining the active region;
a gate structure disposed in the substrate and extending in a first horizontal direction to cross the active region;
bit line structures crossing the gate structure and extending in a second horizontal direction, intersecting the first horizontal direction; and
a contact plug disposed between the bit line structures,
wherein the active region includes a first source/drain region, a second source/drain region, and a channel region,
the first source/drain region and the second source/drain region are spaced apart from each other by the gate structure,
the first source/drain region includes a first lower region and a first upper region on the first lower region,
the first lower region is a first crystal region,
the first upper region is a second crystal region, different from the first crystal region, and
the contact plug contacts the first upper region of the first source/drain region.

2. The semiconductor device of claim 1, wherein a content of a first element in the first upper region is greater than a content of the first element in the first lower region, and the first element includes at least one of carbon (C), silicon (Si), and germanium (Ge).

3. The semiconductor device of claim 1, wherein the first upper region further includes an N-type impurity, and the first lower region includes an N-type impurity.

4. The semiconductor device of claim 1, wherein the first lower region has an etch selectivity with the first upper region.

5. The semiconductor device of claim 1, wherein the first crystal region is a first single crystal region, and the second crystal region is a recrystallized region.

6. The semiconductor device of claim 1, wherein
the channel region has a single crystal structure having a P-type conductivity,
the first crystal region has a single crystal structure having an N-type conductivity, and
the second crystal region has a recrystallized structure having an N-type conductivity.

7. The semiconductor device of claim 1, wherein the contact plug includes a lower portion disposed in the substrate and contacting the first source/drain region and an upper portion disposed on the substrate, and a horizontal width of the lower portion is greater than a horizontal width of the upper portion.

8. The semiconductor device of claim 7, wherein the lower portion protrudes in a horizontal direction toward the first source/drain region.

9. The semiconductor device of claim 7, wherein a vertical thickness of the lower portion of the contact plug is less than a vertical thickness of the first upper region.

10. The semiconductor device of claim 7, wherein the lower portion of the contact plug is spaced apart from the first lower region.

11. The semiconductor device of claim 1, wherein a vertical thickness of the first upper region is about 20 nm to about 30 nm.

12. The semiconductor device of claim 1, wherein the contact plug includes doped polysilicon.

13. The semiconductor device of claim 1, wherein
the second source/drain region includes a second lower region and a second upper region on the second lower region, and
the second upper region includes a material the same as a material of the first upper region and contacts a lower end of one of the bit line structures.

14. The semiconductor device of claim 1, wherein
the second source/drain region includes a second lower region, and
the second lower region includes a material the same as a material of the first lower region and contacts a lower end of one of the bit line structures.

15. The semiconductor device of claim 1, wherein the gate structure is disposed between the first source/drain region and the second source/drain region.

16. The semiconductor device of claim 1, wherein the gate structure is formed in the substrate and disposed in a gate trench extending in the first horizontal direction, and includes a gate dielectric layer covering an inner wall of the gate trench, a gate electrode on the gate dielectric layer, and a gate capping layer on the gate electrode.

17. A semiconductor device comprising:
an active region disposed in a substrate;
a device isolation layer defining the active region;
a gate structure disposed in the substrate and extending in a first horizontal direction to cross the active region;
bit line structures crossing the gate structure and extending in a second horizontal direction, intersecting the first horizontal direction; and
a contact plug disposed between the bit line structures,
wherein the active region includes a first source/drain region, a second source/drain region, and a channel region,
the first source/drain region and the second source/drain region are spaced apart from each other by the gate structure,
the first source/drain region includes a first lower region and a first upper region on the first lower region,
the substrate includes a contact hole formed between the bit line structures and exposing the first upper region and the device isolation layer,
a portion of the contact plug is disposed in the contact hole and contacts the first upper region,
the first lower region has a first etch selectivity with respect to the device isolation layer, and
the first upper region has a second etch selectivity higher than the first etch selectivity with respect to the device isolation layer.

18. The semiconductor device of claim 17, wherein the contact plug includes a lower portion disposed in the contact hole and contacting the first upper region, and an upper portion disposed on the substrate.

19. The semiconductor device of claim 18, wherein the first upper region is in contact with side surfaces and a lower surface of the lower portion of the contact plug.

20. A semiconductor device comprising:
an active region disposed in a substrate;
a device isolation layer defining the active region;
a gate structure formed in the substrate and disposed in a gate trench extending in a first horizontal direction to cross the active region;
bit line structures crossing the gate structure and extending in a second horizontal direction, intersecting the first horizontal direction;
a contact plug disposed between the bit line structures;
a landing pad on the contact plug; and
capacitor structure on the landing pad,
wherein the active region includes a first source/drain region, a second source/drain region, and a channel region,
the first source/drain region and the second source/drain region are spaced apart from each other by the gate structure,
the first source/drain region includes a first lower region and a first upper region on the first lower region,
the first lower region is a first crystal region,
the first upper region is a second crystal region, different from the first crystal region, and
the first upper region of the first source/drain region is in contact with the device isolation layer, the contact plug, and the gate structure.
